(19) United States
(12) Patent Application Publication
(10) Pub. No.: US 2026/0262296 A1
(43) Pub. Date: Sep. 3, 2026

(54) DRAIN EXTENDED TRANSISTOR WITH DYNAMICALLY BIASED FIELD PLATE

(71) Applicant: Texas Instruments Incorporated, Dallas, TX (US)

(72) Inventors: Archana Venugopal, Mountain View, CA (US); Ali Saadat, Santa Clara, CA (US); Timothy Merkin, Princeton, TX (US); Henry Litzmann Edwards, GARLAND, TX (US)

(21) Appl. No.: 19/066,902

(22) Filed: Feb. 28, 2025

(51) Int. Cl. H10D 89/00; H10D 30/01; H10D 30/65; H10D 64/00

(52) U.S. Cl. CPC H10D 89/215; H10D 30/0281; H10D 30/65; H10D 64/112

(57) ABSTRACT

A semiconductor device includes a transistor having a semiconductor layer over a substrate and including a body region having a first conductivity type and a drain drift region having a second conductivity type, a gate dielectric layer over the body region and over a junction between the body region and the drain drift region, a gate electrode over the gate dielectric layer, a drain having the second conductivity type in the drain drift region and having a dopant density greater than the drain drift region, a field relief dielectric layer over the drain drift region and extending from the gate dielectric layer toward the drain region with a thickness greater than the gate dielectric layer, a field plate over the field relief dielectric layer and between the gate electrode and the drain, and a bias circuit to dynamically bias the field plate based on a voltage of the gate electrode.

### BACKGROUND

Drain extended transistors are used in high voltage applications that require high breakdown voltage ratings and efficient operation, including a low drain-source resistance (RDSON) during the on-state along with the ability to block or withstand high off-state voltages between the drain and the source or gate. A lightly doped drift region allows carrier depletion under drain reverse bias so that the drain can block current flow during high voltage operation. The polysilicon gate can be extended across a field relief oxide above the drift region to improve drift region charge balance. However, further reduction in RDSON and increase in off-state blocking voltage is desired.

### SUMMARY

In one aspect, a semiconductor device includes a drain extended transistor having a semiconductor layer over a semiconductor substrate, the semiconductor layer including a body region having a first conductivity type and a drain drift region having a second, opposite, conductivity type, a gate dielectric layer over the body region and extending over a junction between the body region and the drain drift region, a gate electrode over the gate dielectric layer, and a drain region having the second conductivity type in the drain drift region, the drain region having a dopant density greater than a dopant density of the drain drift region. The semiconductor device includes a field relief dielectric layer over the drain drift region, the field relief dielectric layer extending from the gate dielectric layer toward the drain region and having a thickness greater than the gate dielectric layer, a field plate located over one of the field relief dielectric layer and the gate dielectric layer and between the gate electrode and the drain region, and a bias circuit configured to dynamically bias the field plate based on a gate voltage of the gate electrode.

In another aspect, a semiconductor device includes a drain extended transistor having a semiconductor layer over a substrate, the semiconductor layer including a body region having a first conductivity type and a drain drift region having a second conductivity type, a gate dielectric layer over the body region and extending over a junction between the body region and the drain drift region, a gate electrode over the gate dielectric layer, and a drain region having the second conductivity type in the drain drift region. The semiconductor device includes a field relief dielectric layer over the drain drift region, the field relief dielectric layer extending from the gate dielectric layer toward the drain region and having a thickness greater than the gate dielectric layer, a field plate located over one of the field relief dielectric layer and the gate dielectric layer and between the gate electrode and the drain region, and a buried layer having the second conductivity type over the substrate and under the body region, wherein the buried layer is not connected to any electrical node of the drain extended transistor.

In a further aspect, a method of fabricating a drain extended transistor includes providing a semiconductor substrate having a first conductivity type, forming a buried layer having an opposite second conductivity type over the semiconductor substrate, forming a semiconductor layer over the buried layer, the semiconductor layer including a body region having the first conductivity type and a drain drift region having the second conductivity type, forming a gate dielectric layer over the body region and extending over a junction between the body region and the drain drift region, forming a field relief dielectric layer over the drain drift region, the field relief dielectric layer having a thickness greater than the gate dielectric layer, forming a patterned gate electrode over the gate dielectric layer, forming a patterned field plate over one of the field relief dielectric layer and the gate dielectric layer, the patterned field plate spaced apart from the gate electrode, and forming a source region and a drain region, wherein the buried layer is not connected to the patterned gate electrode, the source region, the drain region, and the body region.

### BRIEF DESCRIPTION OF THE DRAWINGS

FIG. 1 is a partial sectional side elevation view of a semiconductor device including a drain extended transistor with a dynamically biased field plate taken along line 1-1 in FIG. 1A.

FIG. 1A is a partial top plan view of the semiconductor device of FIG. 1.

FIG. 2 is a flow diagram of a dynamic field plate biasing method.

FIG. 3A is a graph of specific resistance as a function of field plate biasing voltage.

FIG. 3B is a graph of breakdown voltage as a function of field plate biasing voltage.

FIG. 4 is a partial sectional side elevation view of a semiconductor device including a drain extended transistor with multiple dynamically biased field plates.

FIG. 5 is a flow diagram of a method of fabricating an electronic device.

### DETAILED DESCRIPTION

In the drawings, like reference numerals refer to like elements throughout, and the various features are not necessarily drawn to scale. Also, the term "couple" or "couples" includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms "including", "includes", "having", "has", "with", or variants thereof are intended to be inclusive in a manner similar to the term "comprising", and thus should be interpreted to mean "including, but not limited to". Unless otherwise stated, “about,” “approximately,” or “substantially” preceding a value means +/- 10 percent of the stated value.

One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufactured electronic apparatus such as an integrated circuit. While such examples may be expected to provide various improvements, no particular result is a requirement of the present disclosure unless explicitly recited in a particular claim.

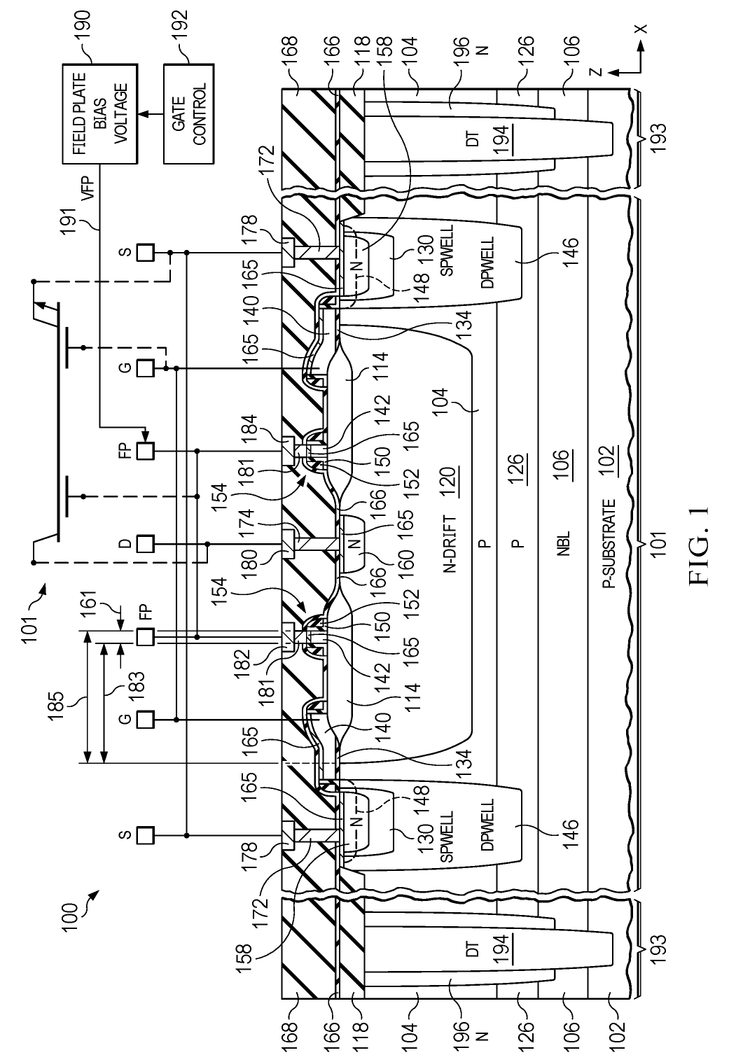

FIGS. 1 and 1A show a semiconductor device 100 that includes a drain extended transistor 101 with a field plate 142 (also schematically designated “FP” in FIG. 1) that is dynamically biased to a field plate voltage VFP by an output 191 of a field plate bias voltage circuit 190 (e.g., labeled “FIELD PLATE BIAS VOLTAGE”) controlled by a gate control circuit 192 based on a gate voltage. The biased field plate 142 may also be referred to as a biased drain field plate. Described examples can enable improved off-state drift region electric field profile uniformity while maintaining good breakdown voltage performance with small half pitch dimensions without increasing the drift region length such that low on-state resistance RDSON of the transistor 101 can be maintained. In conventional DEMOS/LDMOS devices, the gate covers the channel to turn the transistor 101 on or off and the gate can extend over a portion of the drift region to improve the device blocking voltage capability. In one example, the gate poly size of the transistor 101 in FIGS. 1 and 1A can be reduced and the field plate 142 is only biased in the on-state to provide accumulation and reduce RDSON.

The semiconductor device 100 is shown in an example three-dimensional space with a first direction X (FIGS. 1 and 1A), a perpendicular (orthogonal) second direction Y (FIG. 1A), and a third direction Z (FIG. 1) that is perpendicular (orthogonal) to the respective first and second directions X and Y. Structures or features along any two of these directions are orthogonal to one another. The example drain extended transistor 101 is an n-channel laterally diffused metal oxide semiconductor (LDMOS) transistor. FIG. 1 shows a schematic representation of the drain extended transistor 101 with indicated connections to a gate G, a drain D and a source S as well as the field plate FP laterally disposed between the gate G and the drain D. In another implementation, p-channel LDMOS transistors can be formed when n-doped regions are substituted by p-doped regions and p-doped regions are substituted by n-doped regions in another implementation. In one example, further electronic components (not shown) may be provided in the semiconductor device 100, such as a second drain extended transistor interconnected with the illustrated transistor 101 in a half bridge circuit in a packaged integrated circuit with terminals or leads providing external connections to some or all of the transistor terminals. In some implementations, further circuitry can be included, such as a gate driver of the gate control circuit 192 (not shown), switching control timing circuitry, etc., in a single integrated circuit for use in high voltage switching applications such as power conversion systems, transceivers, etc.

The example semiconductor device 100 includes a substrate 102 (FIG. 1), such as including silicon or other semiconductor material from a starting wafer doped with impurities of a first conductivity type (e.g., P-type), such as a silicon (Si) or other semiconductor wafer (e.g., silicon carbide or SiC, gallium nitride or GaN, etc.), a silicon on insulator (SOI) wafer, etc. The semiconductor device 100 in one example includes a semiconductor layer 104 (e.g., p-type epitaxial silicon) that extends over the semiconductor substrate 102 and forms a body region 104 (of the transistor 101) having the first conductivity type (e.g., P-type). An n-type buried layer (NBL) 106 extends under the semiconductor layer 104 and has an opposite second conductivity type (e.g., N-type). The device 100 includes a field relief dielectric layer 114, such as a local oxidation of silicon (LOCOS) layer of silicon dioxide (SiO₂). In one example, an isolation structure including shallow trench isolation 118 extends around the outer periphery of the transistor 101 along and into the top side of the semiconductor layer 104.

The semiconductor device 100 includes a drain drift region 120 (e.g., labelled “N-DRIFT” in FIG. 1) having the second conductivity type and extending in the body region 104. The field relief dielectric layer 114 extends over the drain drift region 120. As shown in FIG. 1A, the example drain extended transistor has a finger or racetrack shape with a center drain finger (e.g., labelled “D” in FIG. 1 and “DRAIN” in FIG. 1A), a polysilicon gate (e.g., labelled “G” in FIG. 1 and “GATE” in FIG. 1A) that encircles the drain, and a source (e.g., labelled “S” in FIG. 1 and “SOURCE” in FIG. 1A) that encircles the gate. In this or other examples, the transistor 101 can include further drain-centered finger or racetrack structures (not shown). In these or other implementations, the transistor can include one or more source-centered finger or racetrack structures and/or one or more gate-centered finger or racetrack structures (not shown).

As further shown in FIG. 1, the example semiconductor device 100 can also include a p-type buried layer 126 (e.g., labelled “P”, also referred to as a pRESURF layer for safe operating area (SOA) improvement) with the first conductivity type and a dopant concentration greater than the body region 104. In one example, the body region 104 of the semiconductor layer includes a shallow well 130 (e.g., labeled “SPWELL” in FIG. 1) below the source S, with the first conductivity type (e.g., p-type) and a dopant density higher than that of the body region 104. The shallow well 130 increases a base doping level of the body region 104 to help suppress a parasitic lateral NPN bipolar transistor formed by an N+ source-p-body-N+ drain D, which may limit high current operation for the LDMOS transistor 101, thus restricting the safe operating area (SOA) of the LDMOS transistor 101.

The transistor 101 also includes a gate dielectric layer 134 (FIG. 1) with a racetrack shape that extends over a portion of the body region 104. The gate dielectric layer 134 extends over a junction between the body region 104 and the drain drift region 120. The gate dielectric layer 134 in one example extends to outer bird’s beak tapered portions of the field relief dielectric layer 114 and over the channel and an interface or junction between the p-type body region 104 and the n-type drift region 120 underneath a portion of the gate fingers or racetrack G. As further shown in FIGS. 1 and 1A, a polysilicon gate electrode 140 extends over the gate dielectric layer 134 and also over a portion of the field relief dielectric layer 114 above the drift region 120.

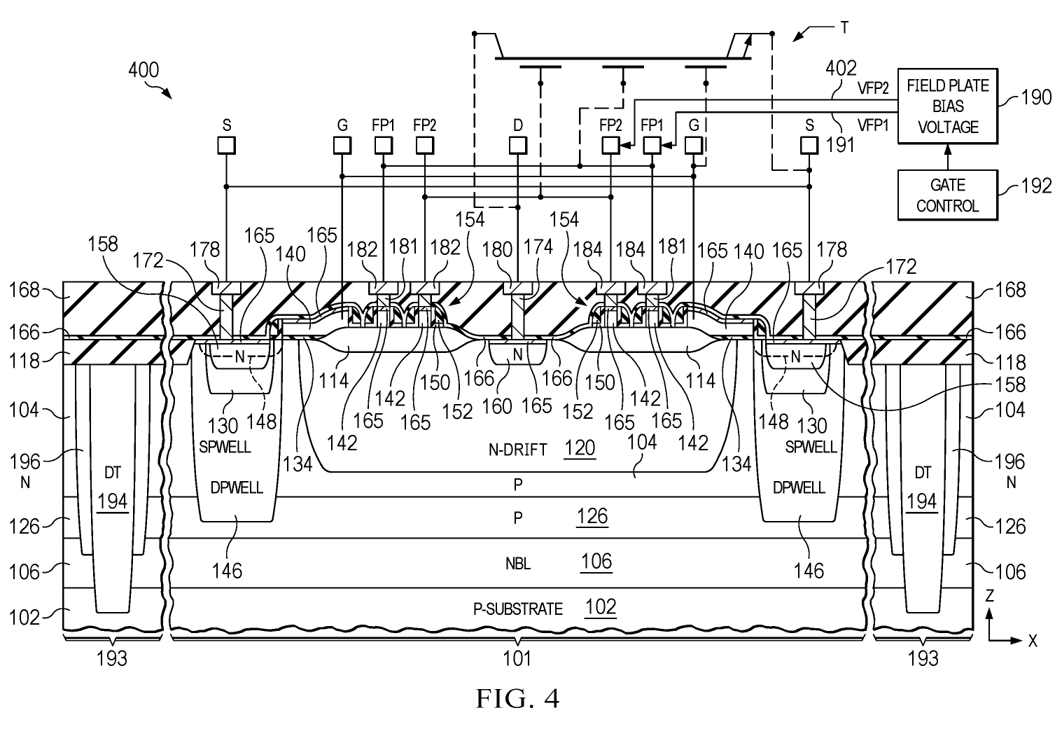

The biased field plate 142, which may also be referred to as a biased drain field plate, is located over the field relief dielectric layer 114. In certain examples, the field plate 142 can be over one or both of the field relief dielectric layer 114 and the gate dielectric layer 134. The biased field plate 142 in this example also has a racetrack shape (e.g., labelled “FP” in FIGS. 1 and 1A). The biased field plate 142 is laterally spaced apart from the gate electrode 140 and is positioned laterally between the gate electrode 140 and the transistor drain. The field plate 142 is conductively connected to the biasing circuit 190 that provides a field plate bias voltage VFP to the field plate 142 in powered operation of the semiconductor device 100. The illustrated example includes a single biased field plate 142. In other implementations (e.g., FIG. 4 below), two or more biased field plates can be provided that are spaced apart from one another and positioned laterally between the gate G and the drain D.

As shown in the example of FIG. 1A, the biased field plate 142 follows a path that has rounded corners with a radius R greater than a thickness (e.g., along the third direction Z in FIG. 1) of the field plate 142. The field relief dielectric layer 114 in one example includes a local oxidation of silicon (LOCOS) layer of silicon dioxide, and the field plate 142 extends over a tapered edge of the field relief dielectric layer 114. In one example, the field plate 142 is or includes polycrystalline silicon and can be formed and patterned concurrently with the gate electrode 140.

The example drain extended transistor 101 also includes a source with a p-type deep well region 146 having the first conductivity type (e.g., labelled “DPWELL” in FIG. 1) that extends through and below the p-type shallow well 130. The p-type deep well region 146 extends to the top side of the body region 104 and connects to the p-type buried layer 126. An n-type well region 148 (FIG. 1) extends along the top side of the p-type deep well region 146 and has the second conductivity type. The example semiconductor device 100 also includes sidewall spacer structures 154 along the lateral sides of the gate electrode 140 and the field plate 142. The sidewall spacers 154 in one example include an oxide layer 150 and a nitride layer 152 formed by deposition and anisotropic etching. In another example, a nitride layer 152 may be deposited across the surface of the wafer and etched to form a nitride-only sidewall spacer 154. The transistor 101 has a source region 158 with the second conductivity type (N-type) in the p-type deep well 146, where the source region 158 has a larger depth than the n-type well region 148.

The transistor drain includes a drain region 160 with the second conductivity type (N-type) extending along and into the top side of the drain drift region 120 in the body region 104 and the drain region 160 is laterally encircled by the field plate 142. The field plate 142 is spaced apart from, and extends laterally between, the gate electrode 140 and the drain region 160. The drain region 160 in one example has a dopant density greater than the dopant density of the drain drift region 120. The field relief dielectric layer 114 extends from the gate dielectric layer 134 toward the drain region 160 and has a thickness greater than the gate dielectric layer 134. The field plate 142 in one example is electrically biased at a non-zero field plate bias voltage with respect to the substrate 102 or with respect to the source. In one example, the field plate 142 extends laterally between the drain region 160 and the gate by a field plate width dimension that is at least twice the thickness along the third direction Z of the field relief dielectric layer 114. In the illustrated example, the field plate 142 is laterally spaced from the thin bird’s beak end of the field relief dielectric layer 114, although not a requirement of all possible implementations. As shown in FIG. 4 below, for example, one or more additional field plates can extend partially or entirely over portions of the field relief dielectric layer in other implementations.

The semiconductor device 100 also includes a metal silicide layer 165 that extend along upper sides of the deep well region 146 of the source and of the drain region 160 to facilitate low resistance electrical connection to the source and drain terminals of the transistor 101. In addition, a metal silicide layer 165 can be provided for low resistance electrical connection to the biased field plate 142 and to the gate electrode 140 by conductive metal (e.g., tungsten) contacts including gate contacts in a gate contact region at the lateral ends of the finger structure (FIG. 1A). The semiconductor device 100 also includes a nitride etch stop layer 166 that extends over portions of the metal silicide 165 and the sidewall spacers 154.

The semiconductor device 100 can include a single or multilevel metallization structure, with a pre-metal dielectric 168 (PMD), conductive metal (e.g., tungsten) contacts 172 and 174 for the respective transistor source and the drain (FIGS. 1 and 1A), as well as gate contacts 176 (FIG. 1A), and field plate contacts 181 (FIGS. 1 and 1A). The illustrated portion of the metallization structure in FIG. 1 also shows metal interconnects 178 and 180 conductively coupled to the respective source and drain contacts 172 and 174, as well as metal interconnects 182 and 184 coupled to the field plate contacts 181, and similar metal interconnects (not shown) are coupled to the gate contacts 176 for electrical connection to the various terminals of the transistor 101 in the metallization structure. The metal interconnects 182 and 184 allow electrical connection of the bias voltage circuit 190 to bias (e.g., dynamically bias) the field plate 142 and a non-zero field plate bias voltage may be applied during on-state operation of the transistor 101.

The extended drain of the transistor 101 provides a relatively lightly doped drift region to extend the high voltage drain away from the edge of the channel region and the lightly doped drift region can be used to increase the reverse blocking voltage beyond the voltage rating of the gate dielectric layer 134 in a particular process. For even higher drain voltage rating, the drain side of the gate polysilicon is spaced (e.g., vertically spaced away) from the drift region 120 by the field relief dielectric layer 114 to facilitate more complete depletion of the drift region. Reduced surface field (RESURF) profiled doping can be used for full reverse bias depletion of the drift region. The drift region doping level or dopant concentration in certain examples can be higher near the connection to the transistor channel region to mitigate channel hot carrier injection into the gate and enhance the transistor reliability. In addition, the biased field plate 142 facilitates enhanced uniformity of the electric field in the drift region 120 below the field relief oxide 114 in the off-state of the transistor 101 to facilitate good breakdown voltage performance of the transistor 101 without adversely impacting the on-state drain-source resistance and without having to increase the lateral length of the drift region along the first direction X.

In power switching circuits, such as DC-DC converters, a high-side switch and a low-side switch may be fabricated as drain extended transistors and a source/back gate terminal of the high-side transistor can be isolated from circuit ground to facilitate high-voltage operation. In addition, shrinking geometries and alignment tolerances of advanced semiconductor manufacturing processes increase the performance impact of non-uniformities such as center-edge differences in device structure locations. Scaling drain extended transistors to reduce the half pitch dimension along the first direction X and/or design of transistors with a fixed half pitch dimension to facilitate higher breakdown voltage ratings can inhibit the ability to balance off-state breakdown voltage performance with low on-state drain-source resistance. The electric field uniformity in the transistor off-state can be tailored for a given design of a field plate width dimension 161 (FIG. 1), the position of the lateral edges of the field plate 142 including spacing distances 183 and 185 in FIG. 1 from the body to drift region p-n junction, as well as for the bias voltage applied to the field plate 142 in on-state transistor operation, along with other structural and process values of the transistor 101 and the fabrication thereof.

In one example, the field plate voltage bias circuit 190 (FIG. 1) is configured when the semiconductor device 100 is powered and operating to provide (e.g., dynamically provide) a non-zero field plate bias voltage VFP to the field plate 142 that is different from the voltage of the gate electrode 140 when the transistor 101 is turned on. Other implementations (e.g., FIG. 4 below) can include more than one biased field plate positioned between the gate and the drain, which are individually biased with different field plate bias voltages that are different from the gate voltage in the transistor on-state. Any suitable bias circuit 190 can be used for single or multiple dynamically biased field plate implementations.

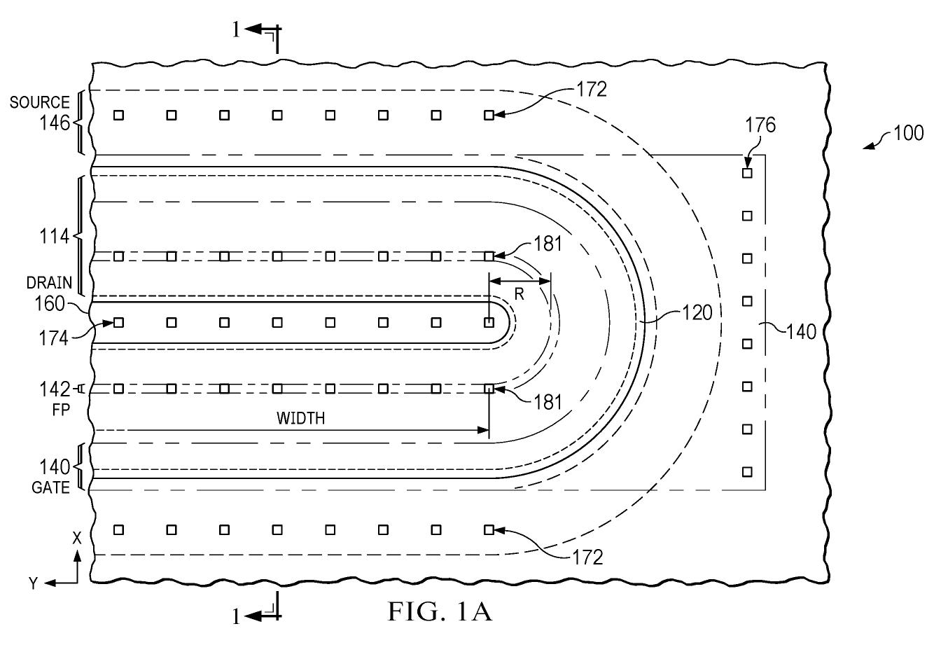

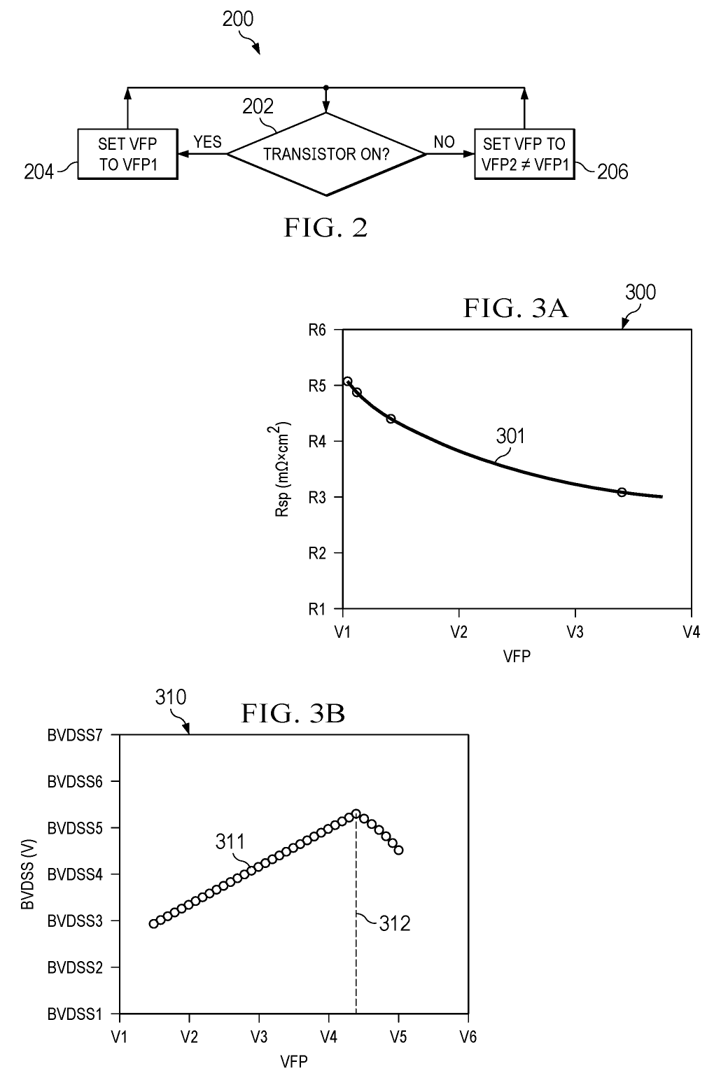

Referring to FIGS. 1, 1A and 2, the bias circuit 190 of FIG. 1 is configured to bias (e.g., dynamically bias) the field plate 142 based on a gate voltage of the gate electrode 140, depending on whether the transistor 101 is turned on or turned off. FIG. 2 shows an example dynamic field plate biasing method 200, which can be implemented by the bias circuit 190 in one example. In one example, the bias circuit 190 is configured to bias the field plate 142 to a first bias voltage VFP1 when the drain extended transistor 101 is turned on, and to bias the field plate 142 to a second bias voltage VFP2 when the drain extended transistor 101 is turned off, where the first and second bias voltages VFP1 and VFP2 are different. In one example, the first bias voltage VFP1 is greater than the second bias voltage VFP2, although not a requirement of all possible implementations. For example, the method 200 in FIG. 2 determines at 202 whether the transistor 101 is turned on, and if so (YES at 202), sets the bias voltage (VFP in FIG. 1) to the first bias voltage VFP1 at 204. Otherwise (NO at 202), the bias voltage is set to the second bias voltage VFP2 at 206. In one example, the second bias voltage VFP2 is less than 5 V. In this or another example, the second bias voltage VFP2 is approximately 0 V. In these or another example, the second bias voltage VFP2 can be approximately equal to the gate voltage when the drain extended transistor 101 is turned off. In another example, the second bias voltage VFP2 can be approximately 5 V in the off-state and the first bias voltage VFP1 can also be approximately 5 V in the on-state to help improve the device electrostatic behavior. In one example, the second bias voltage VFP2 is low (e.g., approximately the same voltage as the gate voltage or slightly higher (e.g., approximately 5V), and the first bias voltage VFP1 can be any suitable voltage to reduce RDSON (e.g., not necessarily higher than VFP2), where higher values for VFP1 are beneficial to reduce the on-state resistances (RDSON), for example, as shown in FIG. 3A below.

Referring also to FIGS. 3A and 3B, FIG. 3A shows a graph 300 with an example drain-to-source specific resistance RSP curve 301 as a function of the first bias voltage (e.g., labeled “VFP in the horizontal axis in FIG. 3A), showing successively higher voltages V1, V2, V3 and V4 along the horizontal axis, where V1 < V2 < V3 < V4. The graph 300 shows successively higher resistances R1, R2, R3, R4, R5 and R6 along the vertical axis, where R1 < R2 < R3 < R4 < R5 < R6. The resistance between the drain and the source is modulated by the biased field plate 142, because a positive bias at the field plate attracts additional electrons to the n-drift region (e.g., drain drift region 120 in FIG. 1), resulting in reduced resistivity of the n-drift region. FIG. 3B shows a graph 310 with an off-state breakdown voltage curve 311 during off-state operation of the transistor 101 as a function of the field plate voltage VFP. The graph 310 shows successively higher voltages V1, V2, V3, V4, V5 and V6 along the horizontal axis, where V1 < V2 < V3 < V4 < V5 < V6, as well as successively higher breakdown voltages BVDSS1, BVDSS2, BVDSS3, BVDSS4, BVDSS5, BVDSS6 and BVDSS7 along the horizontal axis, where BVDSS1 < BVDSS2 < BVDSS3 < BVDSS4 < BVDSS5 < BVDSS6 < BVDSS7. The curve 311 has a maximal or peak value at a field plate voltage 312 as shown in FIG. 3B illustrating a desirable effect of the field plate voltage VFP.

In one example implementation of the transistor 101, the gate size can be reduced compared with conventional LDMOS designs, and the field plate 142 is only biased in the on-state to enhance accumulation and reduce on-state resistance RDSON. In one example, the field plate 142 can be shorted to the gate 140 by the bias circuit 190 when the transistor 101 is off, for example, to minimize the size of the bias circuitry 190. The example device 100 can also improve the performance of high-voltage transistors with relatively large gates over the drift region 120.

As further shown in FIG. 1, the dynamic field plate biasing (e.g., dynamic field plate biasing) can be used alone or in combination with different connections to an isolation tank such as high-side (isolation-to-drain), low-side (isolation-to-source), and floating configurations in conjunction with the buried layer (e.g., NBL 106 in FIG. 1). An isolation tank for the transistor 101 may refer to a combination of the buried layer 106 (e.g., N-type doped) underneath the transistor 101 and an implanted region 196 connected to the buried layer 106 that laterally surrounds the transistor 101. In other words, the implanted region 196 and the buried layer 106 form an isolation tank that contains the drain extended transistor 101. Moreover, a deep trench isolation structure that includes a deep trench 194 filled with silicon dioxide or another insulator (e.g., labeled “DT”) may be part of the isolation tank. The deep trench isolation structure encircles the transistor 101.

For example, in a floating configuration, the buried layer 106 (hence the isolation tank) is not connected to any electrical node of the drain extended transistor 101 as shown in the example of FIG. 1. In other words, the buried layer 106 is electrically floating with respect to the transistor 101 (e.g., not connected to any terminals of the transistor 101). As described above, the buried layer 106 in the example of FIG. 1 is connected to an implanted region 196 (e.g., a deep implanted well) that has the second conductivity type (N-type) and extends between the buried layer 106 and an upper surface of the semiconductor layer 104. In the illustrated example, the implanted region 196 is located underneath a dielectric isolation region, in this case, the shallow trench isolation (STI) 118. The implanted region 196 laterally surrounds the drain extended transistor 101, and the implanted region 196 is not connected to any electrical node of the drain extended transistor 101. The floating NBL 106 can help lower parasitic capacitance, and the combination of dynamic field plate biasing with the floating NBL 106 can further improve device performance in terms of parasitic capacitances. In another implementation, the floating NBL 106 can be used in combination with static (e.g., non-dynamic, field plate biasing independent of a gate voltage or the transistor 101 being turned on or off) field plate biasing for improved performance in terms of lowered parasitic capacitance.

FIG. 4 shows another semiconductor device 400 having similarly numbered features as described above in connection with FIGS. 1 and 1A, with the addition of a second field plate. The multiple field plate implementation can be extended to further added field plates (e.g., any integer number ‘n’ field plates) that can be individually or jointly biased, and the biasing can be static or dynamic, for example, based on whether the transistor is turned on or off. The semiconductor device 400 in FIG. 4 includes a drain extended transistor (e.g., labeled “T” in FIG. 4) that includes various structures and features as described above in connection with the transistor 101 of FIGS. 1 and 1A. In this example, the field plate 142 is referred to as a first field plate (e.g., labeled “FP1” in FIG. 4) and the semiconductor device 400 includes another field plate, namely a second field plate 142 (e.g., labeled “FP2”). The second field plate 142 can be located over one or both of the field relief dielectric layer 114 and the gate dielectric layer 134 and is laterally spaced apart from the first field plate FP1 where the second field plate FP2 can have a racetrack shape that laterally encircles or surrounds the racetrack shaped first field plate FP1.

The bias circuit 190 in one example is configured to dynamically bias the first and second field plates to respective first and second field plate bias voltages VFP1 and VFP2 based on the gate voltage of the gate electrode 140, for example, applying a first bias voltage when the transistor T is turned on and a second (e.g., lower or zero) bias voltage when the transistor T is turned off. The bias circuit 190 in this example has a first output 191 coupled to provide a first bias voltage VFP1 to the first field plate FP1, as well as a second output 402 coupled to provide a second bias voltage (VFP2) to the second field plate FP2. In one example, the bias voltages applied to the first and second field plates 142 can be the same. In another example, the bias voltages applied to the first and second field plates 142 can be different. In one example, the bias circuit 190 provides dynamic field plate biasing to one or both of the field plates FP1 and FP2. In this or another example, the bias circuit 190 provides static field plate biasing to one or both of the field plates FP1 and FP2. As further shown in FIG. 4, moreover, the semiconductor device 400 can have a floating NBL 106 that is not connected to any terminals of the transistor T, similar to the example of FIGS. 1 and 1A above, although not a requirement of all possible implementations.

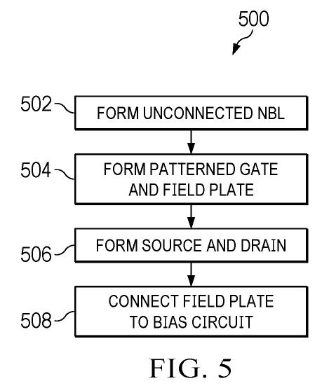

FIG. 5 shows an example method 500 for fabricating an electronic device according to another aspect. The method 500 in one example uses a provided substrate, such as a semiconductor substrate 102 having a first conductivity type (e.g., P-type). At 502 in FIG. 5, a buried layer 106 is formed that has an opposite second conductivity type (e.g., N-type) over the semiconductor substrate 102. In one implementation, a semiconductor layer (e.g., epitaxial silicon layer 104 above) is formed over the buried layer 106, including a body region 104 having the first conductivity type and a drain drift region (e.g., drain drift region 120) having the second conductivity type. One example also includes forming a gate dielectric layer (e.g., the gate dielectric layer 134) over the body region 104 and extending over a junction between the body region 104 and the drain drift region 120, as well as forming a field relief dielectric layer 114 over the drain drift region 120. In one example, the field relief dielectric layer 114 is formed to a thickness greater than the gate dielectric layer 134.

The example method 500 include forming a patterned gate electrode at 504 (e.g., gate electrode 140) over the gate dielectric layer 134 and forming the patterned field plate (e.g., field plate 142) over the field relief dielectric layer 114, where the patterned field plate 142 spaced apart from the gate electrode 140. At 506 in FIG. 5, the method 500 includes forming a source region and a drain region, wherein the buried layer 106 is not connected to the patterned gate electrode, the source region, the drain region, and the body region (e.g., the buried layer 106 is floating with respect to the resulting transistor 101 or transistor T). In one example, the method 500 further includes connecting the field plate 142 to a bias circuit 190 at 505 in FIG. 5, where the bias circuit 190 is configured to dynamically bias the field plate 142 based on a gate voltage of the gate electrode 140. In one implementation, the bias circuit 190 is configured to bias the field plate 142 to a first bias voltage VFP1 when the drain extended transistor 101 is turned on, and to bias the field plate 142 to a different (e.g., lower) second bias voltage VFP2 when the drain extended transistor 101 is turned off.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present description should not be limited by any of the above described examples. Rather, the scope of the disclosure should be defined in accordance with the following claims and their equivalents. Modifications are possible in the described examples, and other implementations are possible, within the scope of the claims.

What is claimed is:

1. A semiconductor device, comprising:
a drain extended transistor having a semiconductor layer over a semiconductor substrate, the semiconductor layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having a dopant density greater than a dopant density of the drain drift region;
a field relief dielectric layer over the drain drift region, the field relief dielectric layer extending from the gate dielectric layer toward the drain region and having a thickness greater than the gate dielectric layer;
a field plate located over one of the field relief dielectric layer and the gate dielectric layer and between the gate electrode and the drain region; and
a bias circuit configured to dynamically bias the field plate based on a gate voltage of the gate electrode.

2. The semiconductor device of claim 1, wherein: the bias circuit is configured to bias the field plate to a first bias voltage when the drain extended transistor is turned on, and to bias the field plate to a second bias voltage when the drain extended transistor is turned off, and the first bias voltage is greater than the second bias voltage.

3. The semiconductor device of claim 2, wherein the second bias voltage is less than 5 V.

4. The semiconductor device of claim 2, wherein the second bias voltage is approximately 0 V.

5. The semiconductor device of claim 2, wherein the second bias voltage is approximately equal to the gate voltage when the drain extended transistor is turned off.

6. The semiconductor device of claim 1, wherein:
the field plate is a first field plate;
the semiconductor device further comprises a second field plate located over the field relief dielectric layer and spaced apart from the first field plate; and
the bias circuit is configured to dynamically bias the first and second field plates to respective first and second field plate bias voltages based on the gate voltage of the gate electrode.

7. The semiconductor device of claim 1, further comprising a buried layer having the second conductivity type over the semiconductor substrate and under the body region, wherein the buried layer is not connected to any electrical node of the drain extended transistor.

8. The semiconductor device of claim 7, wherein the buried layer is floating with respect to the drain extended transistor.

9. The semiconductor device of claim 7, wherein the buried layer is connected to an implanted region that has the second conductivity type and extends between the buried layer and an upper surface of the semiconductor layer.

10. The semiconductor device of claim 9, wherein the implanted region laterally surrounds the drain extended transistor.

11. The semiconductor device of claim 9, wherein the implanted region is not connected to any electrical node of the drain extended transistor.

12. The semiconductor device of claim 9, wherein the implanted region and the buried layer form an isolation tank that contains the drain extended transistor.

13. The semiconductor device of claim 9, wherein the implanted region is located underneath a dielectric isolation region.

14. A semiconductor device, comprising:
a drain extended transistor having a semiconductor layer over a substrate, the semiconductor layer including a body region having a first conductivity type and a drain drift region having a second conductivity type;
a gate dielectric layer over the body region and extending over a junction between the body region and the drain drift region;
a gate electrode over the gate dielectric layer;
a drain region having the second conductivity type in the drain drift region;
a field relief dielectric layer over the drain drift region, the field relief dielectric layer extending from the gate dielectric layer toward the drain region and having a thickness greater than the gate dielectric layer;
a field plate located over one of the field relief dielectric layer and the gate dielectric layer and between the gate electrode and the drain region; and
a buried layer having the second conductivity type over the substrate and under the body region, wherein the buried layer is not connected to any electrical node of the drain extended transistor.

15. The semiconductor device of claim 14, wherein:
the field plate is a first field plate; and
the semiconductor device further comprises:
a second field plate located over the field relief dielectric layer and spaced apart from the first field plate; and
a bias circuit configured to dynamically bias the first and second field plates to respective first and second field plate bias voltages based on a gate voltage of the gate electrode.

16. The semiconductor device of claim 14, further comprising a bias circuit configured to bias the field plate to a first bias voltage when the drain extended transistor is turned on, and to bias the field plate to a second bias voltage when the drain extended transistor is turned off, and the first bias voltage is greater than the second bias voltage.

17. The semiconductor device of claim 14, wherein the buried layer is connected to an implanted region that has the second conductivity type and extends between the buried layer and an upper surface of the semiconductor layer.

18. A method of fabricating a drain extended transistor, the method comprising:
providing a semiconductor substrate having a first conductivity type;
forming a buried layer having an opposite second conductivity type over the semiconductor substrate;
forming a semiconductor layer over the buried layer, the semiconductor layer including a body region having the first conductivity type and a drain drift region having the second conductivity type;
forming a gate dielectric layer over the body region and extending over a junction between the body region and the drain drift region;
forming a field relief dielectric layer over the drain drift region, the field relief dielectric layer having a thickness greater than the gate dielectric layer;
forming a patterned gate electrode over the gate dielectric layer;
forming a patterned field plate over one of the field relief dielectric layer and the gate dielectric layer, the patterned field plate spaced apart from the patterned gate electrode; and
forming a source region and a drain region, wherein the buried layer is not connected to the patterned gate electrode, the source region, the drain region, and the body region.

19. The method of claim 18, further comprising connecting the patterned field plate to a bias circuit, the bias circuit configured to dynamically bias the patterned field plate based on a gate voltage of the patterned gate electrode.

20. The method of claim 19, wherein the bias circuit is configured to bias the patterned field plate to a first bias voltage when the drain extended transistor is turned on, and to bias the patterned field plate to a lower second bias voltage when the drain extended transistor is turned off.
